(19) United States
(12) Patent Application Publication
(10) Pub. No.: US 2009/0148780 A1
(43) Pub. Date: Jun. 11, 2009

(54) METHOD FOR CORRECTING MASK PATTERN, AND EXPOSURE MASK

(75) Inventor: TADAO YASUZATO, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/328,806

(22) Filed: Dec. 5, 2008

(30) Foreign Application Priority Data
Dec. 6, 2007 (JP) 2007-315787

(51) Int. Cl. G03F 1/00

(52) U.S. Cl. 430/5

(57) ABSTRACT

A method for correcting optical proximity effect of a mask pattern for exposure light, the mask pattern including a rectangular pattern formed by a transparent region having a dimension of limiting resolution of exposure light, includes (a) performing exposure by means of an evaluating mask on which an evaluation pattern including the rectangular pattern is arranged so as to form a pattern on a wafer. Further, the method includes (b) calculating an error between a simulation value obtained by a simulation of exposure, the simulation using the evaluation pattern and a dimension value of the pattern formed on the wafer, and (c) optimizing a simulation parameter so that the error becomes small. The simulation parameter includes at least a first bias value and a second value, the first bias value corrects a corner portion of the rectangular pattern, and the second bias value corrects a side portion of the rectangular pattern.

### BACKGROUND OF THE INVENTION

1. Field of the Invention

The present invention relates to a method for correcting a mask pattern, and an exposure mask. This invention particularly relates to a method for correcting a mask pattern used to form a desired device pattern on a wafer, and an exposure mask manufactured by the method.

2. Description of Related Art

In the present optical lithography technology, a shortened wavelength (λ) of exposure light used in an exposure device, a high numerical aperture (NA) of a projector lens and a resolution enhancement technique are applied, whereby a fine pattern 1/2 times or less as large as the exposure wavelength can be formed. Generally, resolution R is expressed by R=k1·λ/NA. This NA is defined by NA=n·sin θ, where θ is a maximum incidence angle at an imaging surface and indicates the magnitude of a projector lens, that is, this magnitude represents how much light that is diffracted by a mask is collected. This n is a refractive index of a medium between a projector lens and a wafer. There are manufactured some exposure devices which have been configured to increase sin θ to around 1 and further to obtain NA>1 by immersion exposure technology in which liquid is filled between the projector lens and the wafer. The k1 is a coefficient that depends on a process of a resist material and the like, and has gradually become small because of improvement of the resist material and high focus accuracy of an exposure device. Thus, the resolution by optical lithography technology has become finer.

The resolution enhancement technique is an approach to improve resolution by optimizing the shape of a light source for mask illumination, an amplitude distribution of transmitted light through the mask or an amplitude distribution at a pupil plane. An exposure master formed with a circuit pattern (also called “mask pattern”) mounted on the exposure device is called a “mask”, but in many cases in which reduction magnification is except “1”, the master is called “reticle”. Hereinafter, the master is called “mask” for convenience. The mask pattern, for example, is formed on the mask by etching so as to form a light shielding film made of chrome or the like on a transparent substrate made of quartz or the like.

As the resolution enhancement technique using the shape of a light source, obliquely incident illumination is known. This obliquely incident illumination refers to a method of cutting vertical incidence light and illuminating a mask with only obliquely incident light because a finer pattern will not cause the illuminating light that enters the mask to contribute to resolution. In the case of the proposed ordinary illumination, forming an image of a repetitive pattern requires convergence of zero-order light and ± first-order lights of diffraction light, which is called “three-beam interference”. On the other hand, in the case of obliquely incident illumination, one of ± first-order lights is discarded and an image of the same repetitive pattern as the original pitch is formed by two-beam interference of zero-order light and the other of ± first-order lights.

In the obliquely incident illumination, discarding one of ± first-order lights worsens balancing with zero-order light and degrades contrast at the best focus. However, the incidence angle at the imaging surface becomes 1/2 times as large as the ordinary illumination that is being proposed, so that the decrease in contrast at defocus becomes less, thus increasing the depth of focus. The depth of focus refers to a focus range in which the effective resist pattern can be obtained.

As the resolution enhancement technique that uses a mask, a phase shifting mask is well-known and various types of systems such as Shibuya-Levenson system or halftone system have been proposed. A phase shifting mask of the halftone system, hereinafter called a “halftone phase shifting mask”, refers to the phase shifting mask that is obtained by leaking a little light in a range of light shielding of the mask and reversing a phase of the leaked light by 180 degrees from a phase of the transmitted light through an opening (i.e., a transparent region). This transparent region has a dimension of limiting resolution of exposure light. The halftone phase shifting mask is often used because it is easy to apply. The light shielding film of the mask generally uses metal chrome, while the halftone phase shifting mask uses a translucent film made of compounds such as metallic oxide, oxidized nitride (e.g., MoSiON) and metallic fluoride (e.g., CrF). Additionally, it is known that in a hole pattern of the opening of the mask, the amplitude distribution of the transmitted light through the mask is of Bessel function, whereby the depth of focus becomes maximum. In the halftone phase shifting mask, a negative amplitude is formed in the transmitted light through a translucent film, and thus the amplitude of the transmitted light is brought near the Bessel function, and the depth of focus can be increased.

A Shibuya-Levenson phase shifting mask, hereinafter called “Levenson phase shifting mask”, has a mechanism that alternately reverses the phases of the transmitted light of adjacent openings on a mask by 180 degrees. Clear dark portions can be formed by the interference of light whose phases have been reversed. Thus, a fine opening can be separated and resolved. In the obliquely incident illumination, illumination light enters obliquely, thereby generating a phase difference due to optical path difference. Further, in the Levenson phase shifting mask, the phase difference is controlled by the optical path difference due to unevenness (or a transparent film) that is etched on a mask substrate. Therefore, the resolution enhancement technique using the obliquely incident illumination and the Levenson phase shifting mask produces the effect of enhancing resolution on a dense pattern where diffracted light occurs.

However, it is known that the resolution enhancement technique that is effective in the dense pattern has adverse effects such as a reduction in the depth of focus when a sparse pattern in which the diffracted light is not generated partly exists. Thus, a method called an auxiliary pattern has been proposed in which a fine pattern which itself is not transferred is arranged around the sparse pattern so as to come closer to the dense pattern.

Although the application of the resolution enhancement technique enhances resolution, a considerable amount of information of the mask pattern that is formed on a mask is lost on a wafer that is an imaging surface, which results in a problem in which the deformation and dimensional fluctuations of a resist pattern are generated on the wafer. This arises from the fact that although diffraction that is generated when exposure light passes through the mask pattern corresponds to Fourier transform and the imaging by means of a projection lens corresponds to inverse Fourier transform, the projection lens functions as a low-pass filter. Namely, higher-order diffracted light does not pass through the projection lens among the diffracted lights having information on respective orders (the zero-order, first-order, second-order and higher-order) in Fourier transform. Therefore, only the lower-order diffracted light undergoes the inverse Fourier transform to lose the information of the mask pattern which the higher-order diffracted light has. For example, when the resolution enhancement technique is applied, the densest pattern causes imaging of only the zero-order and first-order diffracted light, denser patterns cause imaging of the zero-order and ± first-order diffracted light, and sparser patterns cause imaging of the higher order diffracted light. Thus, the dimensional difference in the pattern on the wafer becomes large, thereby causing apparent deformation in a two-dimensional pattern.

As measures to correct deformation in the aforementioned two-dimensional pattern, one method called an Optical Proximity Correction (hereinafter called the OPC) has been proposed, in which the mask pattern is corrected so as to obtain a desired shaped or dimensional pattern on the wafer. The OPC is used herein in a broad sense to correct not only the optical deformation in a projection device but also to correct factors in every process step until a pattern is formed on the wafer from the mask data of CAD.

The OPC is classified into a model based OPC and a rule based OPC. The model based OPC is a process in which the pattern on the wafer is simulated and the mask data is corrected so that the pattern obtained by this simulation becomes a targeted pattern. Meanwhile, the rule based OPC is a process in which a table (i.e., a rule) on a correction amount corresponding to line widths and intervals is created in advance, and the mask data is corrected according to this rule. The rule based OPC can achieve the same correction as that of the model based OPC if the rule is perfectly created. However, the rule based OPC has a problem in which vast amounts of man hours are required to create the rule.

In the model based OPC, processing for optimizing every kind of simulation parameter and for producing the collection of polar coordinate functions called a kernel, hereinafter called “preparation of the OPC model” are performed so as to reduce differences between the simulated and actual dimensional measured values. The kernel indicates the distribution of light on the wafer and is used to calculate light intensity in a predetermined position on the wafer at a high speed, The calculated light intensity is used to estimate a resist pattern.

In general, the range of practical computation is only several dozen μm since the optical formula used in a lithography simulator includes integral calculation. In contrast, the OPC requires calculation of the light intensity on the whole wafer, so that the product of CAD data, which indicates the mask pattern, the kernel and a predetermined coefficient, is calculated instead of the optical formula. A process for calculating the light intensity on the whole wafer by adding the product is used. According to this process, the light intensity is obtained by multiplications and additions without integral calculation, thus enabling high-speed calculation. In the model based OPC, the OPC model is produced with relative ease, so as to be promptly transferred to the correction process of the mask data (also called an “OPC process”) accordingly. However, the OPC process itself of the model based OPC is known to be slower than that of the rule based OPC.

Additionally, in normal lithography simulation, the distribution of the light intensity on the wafer is calculated using so-called Kirchhoff approximation in which the thicknesses of the light shielding film of the mask and the translucent film are ignored. However, it has been pointed out that the thickness of the mask (unevenness) cannot be ignored when the dimension of the mask pattern becomes approximately the same as the wavelength of the exposure light due to improvement of the resolution by means of optical lithography technology. Namely, the mask pattern has the dimension of limiting resolution of exposure light. The influence of the unevenness on the mask is called the mask 3D effect (or the mask topography effect). Also in the model based OPC, a method for improving the dimensional accuracy by adopting the mask 3D effect has been proposed.

In the Levenson phase shifting mask, a method for correcting the mask 3D effect as a mask bias has been proposed since the early stage of the development (refer to JP-A-2005-309202). Furthermore, since strict calculations that take into consideration the mask structure have become possible in recent years, it has been shown that in a binary mask that includes a light shielding area and a translucent area, the light shielding area uses normal metal as the light shielding film, and the mask 3D effect can be handled as the mask bias (refer to Proceedings of SPIE Vol, 5754, pp. 528-536). Moreover, it has been shown that in a halftone phase shifting mask, the mask 3D effect can be handled as the mask bias by means of simple approximation. For example, even if the mask 3D effect works as the mask bias and as a phase error (the deviation from 180 degrees in the phase difference), it can be handled as the mask bias because the influence of the phase error is small when the obliquely incident illumination is used.

### SUMMARY

However, in handling the mask 3D effect as a mask bias, vast amounts of calculation time are required even if the influence of the mask 3D effect is exactly simulated (e.g., preparation of OPC model). This problem is caused by the following phenomenon: the mask 3D effect exists in a corner portion at the front end of a hole pattern or a space pattern. Further, in that corner portion, the above-described problem has occurred due to rounding of an electric beam in mask lithography caused by blunting (rounding) of the corner portion of the metallic aperture that forms the electronic beam, and due to rounding caused by resolution (developing) of a resist.

The present invention seeks to solve one or more of the above problems, or to improve upon those problems at least in part.

The first aspect of the present invention provides a method for correcting optical proximity effect of a mask pattern for exposure light, the mask pattern including a rectangular pattern formed by a transparent region having a dimension of limiting resolution of exposure light, comprising: performing exposure by means of an evaluating mask on which an evaluation pattern including the rectangular pattern is arranged so as to form a pattern on a wafer; calculating an error between a simulation value obtained by a simulation of exposure, the simulation using the evaluation pattern and a dimension value of the pattern formed on the wafer; and optimizing a simulation parameter so that the error becomes small, wherein the simulation parameter comprises at least a first bias value and a second value, the first bias value corrects a corner portion of the rectangular pattern, and the second bias value corrects a side portion of the rectangular pattern.

The second aspect of the present invention provides an exposure mask manufactured based on mask data, wherein the mask data undergoes correction of the optical proximity effect by a method for correcting optical proximity effect of a mask pattern for exposure light, the mask pattern including a rectangular pattern formed by a transparent region having a dimension of limiting resolution of exposure light, comprising: performing exposure by means of an evaluating mask on which an evaluation pattern including the rectangular pattern is arranged so as to form a pattern on a wafer; calculating an error between a simulation value obtained by a simulation of exposure, the simulation using the evaluation pattern and a dimension value of the pattern formed on the wafer; and optimizing a simulation parameter so that the error becomes small, wherein the simulation parameter comprises at least a first bias value and a second value, the first bias value corrects a corner portion of the rectangular pattern, and the second bias value corrects a side portion of the rectangular pattern.

According to a method for correcting a mask pattern of the present invention, bias values for correcting the dimension of a rectangular pattern are individually set for a corner portion and a side portion. Therefore, the influence of the mask 3D effect and rounding caused by resolution of resist on a wafer are corrected at the corner portion and the side portion, which are differently influenced, but are not corrected for the whole rectangular pattern. Accordingly, calculation required for optimization can be simplified for high-speed calculation.

### BRIEF DESCRIPTION OF THE DRAWINGS

The above features and advantages of the present invention will be more apparent from the following description of certain preferred embodiments taken in conjoining with the accompanying drawings, in which:

FIG. 1 is a flowchart illustrating a method for correcting a mask pattern according to a first exemplary embodiment of the present invention;

FIG. 2 is a view illustrating an image on CAD data when a fitting (i.e., optimization) for individually setting bias values is performed;

FIG. 3 is a flowchart illustrating a method for correcting a mask pattern according to a second exemplary embodiment of the present invention;

FIG. 4 is a graph used in calculating a bias value of a side; and

FIG. 5 is a graph used in calculating a bias value of a corner.

### DETAILED DESCRIPTION OF EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

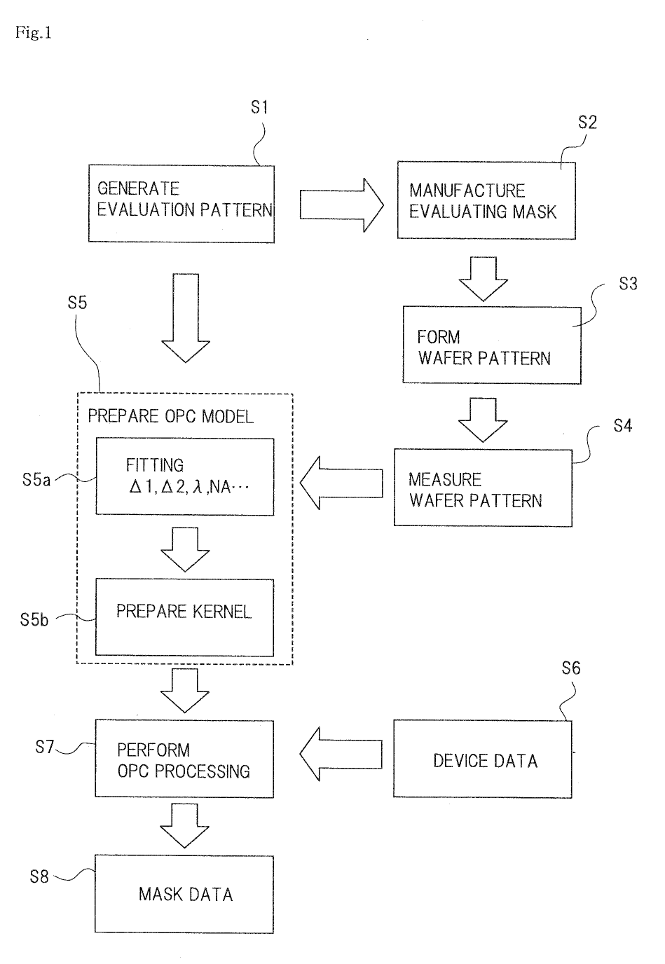

FIG. 1 is a flowchart illustrating a method for correcting a mask pattern according to a first exemplary embodiment of the present invention, where there is shown a procedure for obtaining mask data in order to prepare an exposure mask, hereinafter simply called a “mask”. The mask is used in an exposure process, by which a desired device pattern, where a hole pattern and a space pattern are mixed on a wafer (not shown), is formed. An ArF exposure device (exposure wavelength λ=193 nm) which uses the mask has a reduction magnification of 4, and the optical condition is ordinary lighting of NA=0.92 and coherent factor σ=0.5.

The mask is a halftone phase shifting mask. This mask is formed by a transparent substrate using synthetic quartz (SiO₂), and a translucent film (film thickness=71.85 nm, permeability=5%) using molybdenum silicide oxide and nitride (MoSiON) and the like. The refractive index (n, k) of the transparent substrate is (1.474, 0) at the exposure wavelength of 193 nm. Similarly, the refractive index (n, k) of the translucent film is (2.343, 0.586) at the exposure wavelength of 193 nm. These n, k respectively refer to a real part and an imaginary part, when the refractive index is indicated by a complex refractive index. Further, the angle of a side wall in which a translucent film is etched is approximately 90 degrees to the transparent substrate. A light shielding effect that is generated at the side wall when the translucent film is etched generates a mask 3D effect. Now, each step of the method for correcting a mask pattern will be described below.

The method for correcting a mask pattern is OPC in view of the mask 3D effect and includes steps that are mainly based on the approach of a model based OPC. First, using an evaluation pattern generating tool, an evaluation pattern is generated (S1). The evaluation pattern is CAD data obtained by changing a dimension and a pitch according to the device pattern where the hole patterns and the space patterns are mixed. Moreover, the evaluation pattern satisfies design criteria showing the dimensions and pitch ranges of available hole patterns, space patterns, lines and the like for forming the device pattern on a mask.

Next, an evaluating mask, on which evaluation patterns generated in step S1 are arranged, is manufactured (S2). Exposure is performed by means of the evaluating mask and a wafer pattern is actually formed on a wafer (S3). Subsequently, the dimension of the wafer pattern is measured (S4). Here, the mask on which the evaluation patterns are arranged is called an “evaluating mask”. This may be a mask used for actual preparation of the device and the evaluation patterns may be arranged in a vacant region thereof. There may be a mask for simple process evaluation that is not used for device preparation. In addition, if a number of types of dimensions and pitches, which are capable of preparing OPC model, exist, the evaluation pattern may use the device pattern.

Then, an OPC model is prepared (S5). In step S5, an error between a simulation value, which is obtained from simulation of exposure, the simulation using the evaluation pattern prepared in step S1, and an actual measured value of the wafer pattern measured in step S4 is calculated, and optimization (hereinafter, this optimization is also called “fitting”) of various types of simulation parameters is performed so that the error becomes small (S5a). Then, a set (kernel) of a polar coordinate function showing light distribution on the wafer and a predetermined coefficient corresponding to the kernel are generated (S5b) to complete preparation of an OPC model. The kernel is used to calculate light intensity at a predetermined position on the wafer at a high speed.

The simulation parameters are those required to calculate light intensity, such as exposure wavelength λ, the number of openings NA and coherent factor σ. These λ, NA and σ are predetermined under the above-described optical conditions, but the definition of these parameters set in an exposure device may not be completely the same as the definition of these parameters in a simulation. Therefore, it is also necessary to optimize the values of these parameters.

Furthermore, in this exemplary embodiment, it is noted that, at a corner of the hole pattern or space pattern end, there occurs not only a mask 3D effect but also a) rounding of an electronic beam of the mask drawing (rounding of a corner caused during irradiation of an electronic beam) or b) rounding due to resolution of the resist because developing progresses from inside during the developing period when a resist pattern, that uses positive resist, is developing. Bias values are individually set at the corner (corner portion) and a portion (side portion) other than the corner, and a bias value Δ1 of the corner portion and a bias value Δ2 of the side portion are added as simulation parameters.

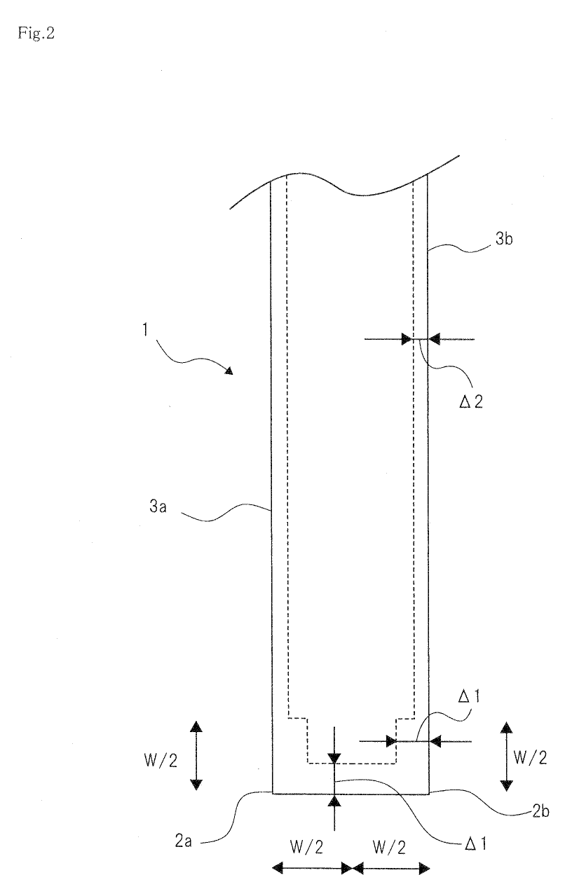

FIG. 2 illustrates an image on CAD data in performing a fitting (optimization) for individually setting bias values of a corner and a side. Here, the front end of a space pattern is illustrated in a top view. Space pattern 1 includes corners 2a, 2b and sides 3a, 3b. Corners 2a, 2b are formed at the front end portions of the slender rectangular pattern. Sides 3a, 3b are extended from corners 2a, 2b and formed substantially parallel to each other. The width dimension (minimum width) of a rectangular pattern is taken as w. In space pattern 1, as illustrated, a bias value in a range from corners 2a, 2b to a point of distance w/2 at a maximum from corners 2a, 2b (this range is also called corner portions 2a, 2b), respectively is taken as Δ1. Further, the bias value of sides 3a, 3b except the range from corners 2a, 2b to w/2 is taken as Δ2 (this range is also called corner portions 3a, 3b). Similarly, in the hole pattern (not shown), a bias value in the range from corners 2a, 2b to w/2 at a maximum is taken as Δ1, and a bias value at sides 3a, 3b except the range from corners 2a, 2b to w/2 at a maximum is taken as Δ2.

As one example, fitting (optimization) is performed with a bias value Δ1 of 9 nm and a bias value Δ2 of 6 nm, such that an error between a simulation value and actual measured values of a space pattern and a hole pattern on the wafer is minimum. Hence, the bias value Δ1 of corners 2a, 2b is set larger than the bias value Δ2 of sides 3a, 3b because the effect of rounding due to electronic beam or resist phenomenon as well as the mask 3D effect is taken into consideration in sides 3a, 3b.

Namely, although the magnitude of the above-described effect is different, bias values corresponding to the magnitude of the effect are individually set at corners 2a, 2b and sides 3a, 3b as compared to the case in which only one bias value of space pattern 1 is set for the fitting (optimization). Thereby, calculation of the fitting for minimizing an error is simplified, so that the time required for calculation is reduced.

Next, the device data in which the device pattern is shown in a desired dimension is input (S6). Using an OPC model prepared in step S5 and the input device data, OPC processing is performed (S7). Then, mask data is output (S8). OPC processing in step S7 multiplies a kernel generated in step S5b, a coefficient and input device data. This device data is, for example, work data from a target position of light intensity to a particular area, and a portion with a pattern is defined as 1 and a portion without a pattern is defined as 0 by means of this data. This multiplication is repeated in the whole wafer surface, and the result of multiplication is added. Thus, light intensity distribution on a wafer can be calculated at a higher speed than that of an ordinary lithography simulator using an optical formula including integration calculation. As a result, a dimension of a transfer pattern on a wafer corresponding to the input device pattern can be calculated at a high speed.

Moreover, in OPC processing, a mask pattern is gradually corrected until a calculated dimension of a transfer pattern almost meets the desired device pattern on a wafer, For example, in correcting a side having a rectangular pattern, other portions are in a pre-correction state. Therefore, correction is made at all sides, and according to this result, a deviation occurs when a dimension of a transfer pattern on the wafer is calculated again. Thus, the result that converges by repeating this loop several times is output as mask data in step S8.

According to the method for correcting a mask pattern of this exemplary embodiment, in applying OPC to the mask pattern in which the hole pattern and the space pattern are mixed, the effects of an electronic beam and a resist that develops at the corner as well as the mask 3D effect are considered. Further, for the corner portion and the side portion, in which the effect on each is different from the other, fitting (optimization) is performed by individually set bias values Δ1, Δ2. Therefore, preparation of an OPC model in step S5 can be made at a high speed.

In addition, when an OPC is performed, in which the proposal is made that bias values Δ1, Δ2 not be set as a simulation parameter for the mask pattern in which the hole pattern and the space pattern have been mixed with each other, a pattern formed on a wafer sometimes has a small hole pattern and size adjustment to the space pattern is difficult. Thus, in the hole pattern, the following causes are considered. The energy of transmitted light is small and light intensity distribution on the wafer becomes low, and therefore the influence of a decrease in energy due to corner rounding becomes exceptional. Meanwhile, in the space pattern, the energy of transmitted light is large, light intensity distribution on a wafer becomes high, and further, the center of the space pattern is located away from the center of the transfer pattern. Thus, in the space pattern, the following causes are considered. The influence of a decrease in energy due to rounding of the corner is small, and the dimension on a wafer does not become so small.

On the other hand, according to the method for correcting a mask pattern of this exemplary embodiment, a bias value Δ1 of the corner is set larger than a bias value Δ2 of the side. Therefore, OPC processing in step S7 calculates the light intensity of a hole pattern to be lower than that of the space pattern and hence the hole pattern is corrected to be larger by just that much while the above-described loop is being repeated. Accordingly, easy size adjustment is attained between the hole pattern and the space pattern.

Moreover, an OPC model can be obtained by simulation parameters of fitting (optimization) including bias values Δ1, Δ2 individually set at the corner and the side. Mask data is prepared from the OPC model through OPC processing. Thus, exposure that uses a mask that is prepared on the basis of this mask data allows a desired mask pattern to be formed on a wafer.

### Second Exemplary Embodiment

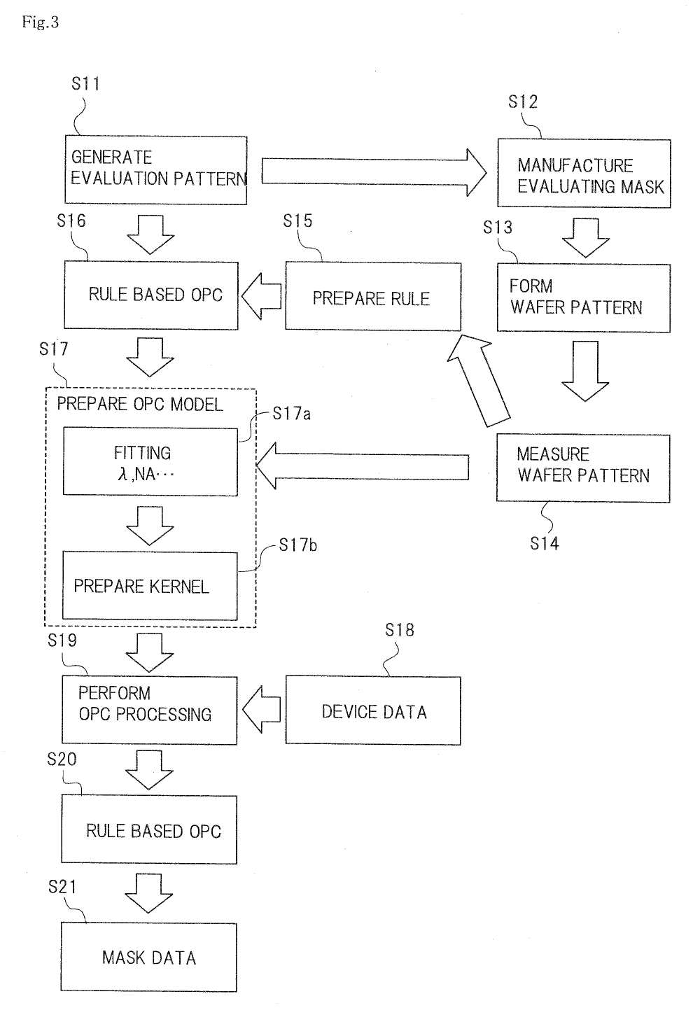

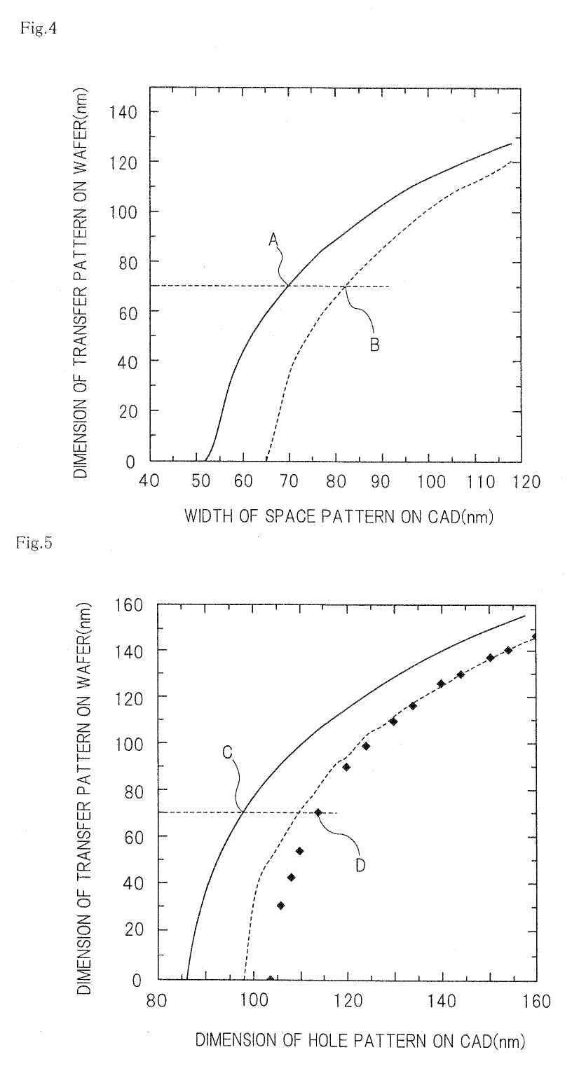

FIG. 3 is a flowchart illustrating a method for correcting a mask pattern according to a second exemplary embodiment of the present invention. For portions of descriptions that overlap with those of the method for correcting a mask pattern illustrated in FIG. 1, those descriptions will not be repeated below as needed. The method for correcting a mask pattern according to this exemplary embodiment is mainly different from that illustrated in FIG. 1, wherein a rule based OPC as well as a model based OPC is applied. For example, as a rule for correcting a side, a bias value Δ2 is calculated by means of simulation (refer to FIG. 4). Then, as a rule for correcting a corner, a bias value Δ1 is calculated by an experiment (refer to FIG. 5). Then, using these bias values Δ1, Δ2, the rule based OPC is performed.

First, in the method for correcting a mask pattern, a bias value Δ2 of a side of a rule used for the rule based OPC is previously calculated by means of simulation. FIG. 4 illustrates a simulation result with the space pattern in both cases in which the mask 3D effect is not considered, that is, Kirchhoff approximation and in which the mask 3D effect is considered. The space pattern is different from the hole pattern and the influence of rounding is minor. Thus, based on a difference in the simulation result of a space pattern by the presence or absence of the mask 3D effect, the bias value Δ2 of a side is calculated.

More specifically, in FIG. 4, the horizontal axis indicates the width dimension of a space pattern on CAD data. The vertical axis indicates a dimension of a transfer pattern on a wafer by means of simulation. In addition, the calculation result without taking into account the mask 3D effect is indicated by a solid line, while the calculation result that takes into account the mask 3D effect is indicated by a dotted line. As one example, description will be made regarding a calculation method for a bias value Δ2 in forming a space pattern of 70 nm in the width dimension on a wafer. In this case, as illustrated, the width dimension on CAD data is 68 nm (refer to intersection A) in the simulation (solid line) without taking into consideration the mask 3D effect. Meanwhile, 80 nm is indicated in the simulation (dotted line) taking into consideration the mask 3D effect. Since the bias of a side occurs on both sides of the space pattern, 6 nm, that is, a half of the value of 12 nm obtained by subtracting 68 nm from 80 nm is set as a bias value Δ2 of a side due to the mask 3D effect.

In the method for correcting a mask pattern according to this exemplary embodiment, an evaluation pattern is generated using an evaluation pattern generating tool (S11). Next, an evaluating mask is manufactured so that the evaluation pattern generated in step S11 is arranged with the evaluating mask (S12). Exposure is performed by means of an evaluating mask by changing the focus and exposure amount so as to form a wafer pattern (S13). Using a space pattern of 80 nm in the width dimension obtained through simulation (dotted line) when taking into consideration the mask 3D effect illustrated in FIG. 4, the exposure amount for forming a pattern of 70 nm in the width dimension on a wafer is searched. Based on the exposure amount and focus conditions, the dimension of a wafer pattern is measured (S14).

Then, in the rules used for the rule based OPC, the bias value Δ1 of a corner is calculated, and preparing the rules of the rule based OPC is performed in combination with a bias value Δ2 of a side (S15). FIG. 5 illustrates a simulation result and the actual measured result (experiment) with a hole pattern in both cases in which the mask 3D effect is not taken into consideration and in which the mask 3D effect is taken into consideration. In FIG. 5, the horizontal axis indicates the width dimension of the space pattern on a CAD. The vertical axis indicates a dimension of a transfer pattern on a wafer by means of simulation and actual measurement. Additionally, a calculation result without taking into consideration of the mask 3D effect is indicated by a solid line.

The hole pattern used herein has a shape such that this pattern is surrounded by a corner. Hence, the hole pattern is different from the space pattern and is largely influenced by rounding, and it is thought that the dimension of a transfer pattern changes according to the inclination of a side wall in which a translucent film is etched. Accordingly, assuming that there is no rounding influence or a side wall having a taper angle, a calculation result that takes into consideration the mask 3D effect is indicated by a dotted line in FIG. 5.

Moreover, in FIG. 5, an actual measured value is indicated by plural points. Regarding the dimension of a transfer pattern, as illustrated an actual measured value (plural points) is smaller than a simulated value (a dotted line) in view of mask 3D. This result comes from rounding and the inclination of a side wall. Thus, it is difficult to accurately simulate values due to the influence of rounding and the inclination of the side wall, so that an actual measured value is used herein.

A correction rule for a corner is prepared by means of such a simulation and experiment. As one example, description will be made regarding a method for calculating a bias value Δ1 in forming a hole pattern of 70 nm on a wafer. In this case, as illustrated in FIG. 5, by means of simulated values (indicated by a solid line) without taking into consideration of the mask 3D effect, the dimension on CAD data is 98 nm (refer to intersection C), while the actual measured value (plural points) is 114 nm. Bias of a corner occurs at all corners of the hole pattern. Accordingly, the bias value Δ1 of the corner is 8 nm, that is, the half of 16 nm obtained by subtracting 98 nm from 114 nm. Hence, in step S15, correction rules for the side and corner are prepared.

Then, in the method for correcting a mask pattern, by applying the rule prepared in step S15 to an evaluation pattern generated in step S11, the rule based OPC is performed (S16). Here, an OPC model obtained by subtracting bias values Δ1, Δ2 for the mask 3D effect from CAD data is prepared. Namely, each side of the space pattern of the width dimension 80 nm obtained because of the mask 3D effect is thinned by a bias value Δ2 (6 nm) so as to have the width dimension of 68 nm. Similarly, each side of the hole pattern of the actually measured dimension of 114 nm is thinned by a bias value Δ1 (8 nm) so as to have the width dimension of 98 nm.

Then, using both the OPC model that has been corrected and prepared with the rule based OPC in step S16 and the actual measured value of the wafer pattern obtained in step S14, an OPC model is prepared (S17). Here, the bias due to the mask 3D effect by means of the rule based OPC in step S16 has been already removed. That is, fitting (optimization) in step S17a does not include the bias values Δ1, Δ2 as simulation parameters. After this fitting (optimization), kernel and a predetermined coefficient corresponding to this kernel are generated so as to complete preparation of an OPC model (S17b).

Next, device data is input (S18). The sum of products of both the OPC model not including the mask 3D effect prepared in step S17b and the device data is calculated for OPC processing (S19). The rule based OPC with the mask 3D effect added is performed for output data by OPC processing in step S19 (S20). In the rule based OPC of step S20, in contrast to the rule based OPC of step S16, the bias value Δ2 of a side is added to the thinned space pattern of the width dimension of 68 nm to increase it to 80 nm. Meanwhile, a bias value Δ1 of a corner is added to the thinned hole pattern of 98 nm to increase it to 114 nm. Hence, the result of the rule based OPC in step S20 becomes final mask data (S21).

According to the method for correcting the mask pattern of exemplary embodiments, bias values Δ1, Δ2 are not included as simulation parameters. Therefore, in case a mask manufacturing process changes, measures to be taken become easy. Namely, improvement in the mask manufacturing process reduces rounding of a corner. Even if the bias value Δ1 affected by the mask 3D effect and rounding becomes small, a second calculation of only the bias value Δ1 can prepare mask data without need for second preparation of the OPC model in step S17.

Moreover, preparation of the OPC model in step S17 and OPC processing in S19 does not include bias values Δ1, Δ2. Accordingly, preparation of the OPC model and OPC processing can be made at a higher speed than the speeds of steps S5 and S7 illustrated in FIG. 1.

In the respective embodiments described above, description is made regarding a halftone phase shifting mask used for ArF excimer laser exposure. However, exemplary embodiments are not limited thereto. A reflex type mask of EUV (wavelength of 13 nm), that is, a mask having a pattern that is formed by a light absorbing material on a laminated reflective mirror, a binary mask and the like are applicable regardless of the wavelength and types of the mask. As one example, a Levenson phase shifting mask with mask substrate etched to control a phase difference is applicable. Regarding this mask, it is sufficient to individually set (a) respective biases of a corner and a side of a portion not etched in a mask substrate and (b) respective biases of a corner and a side of a portion etched in the mask substrate.

Additionally, in steps S1 and S11, an evaluation pattern generated with the evaluation pattern generating tool is used. However, exemplary embodiments are not limited thereto. When the setting of an exposure device, a wafer structure, a register and the like are changed, an actual device pattern may be used.

Furthermore, the exposure wavelength λ, the number of openings NA, the coherence factor σ and bias values Δ1, Δ2 are shown as simulation parameters. Exemplary embodiments are not limited thereto. For example, it is known that in predicting a resist shape from a light intensity distribution, lessening light intensity by means of normal distribution can obtain a state nearer to an actual resist shape than in predicting the resist shape from a threshold value. Regarding this normal distribution, the width of normal distribution called diffusion length can be also used as the above-described parameters. Moreover, when a fitting (optimization) to the dimensions of a pattern is performed after etching, a bias is added as functions of space pattern interval and data rate when taking into consideration deposit and the like during etching. Therefore, the configuration and coefficients of these functions may be taken as the above-described parameters.

According to the method for correcting a mask and the exposure mask of the present invention, adoption of the following aspects is possible. The first bias value (Δ1) is larger than the second bias value (Δ2). Thus, the corner portion can be corrected to be larger than the side portion.

The first bias value includes at least a bias due to the mask 3D effect generated by unevenness between a transparent area and areas other than the transparent area and a bias due to rounding of the corner portion resulting from irradiation of the electronic beam. The second bias value includes a bias due to the mask 3D effect. Thereby, the corner portion requires a larger correction than the side portion.

A rectangular pattern includes a hole pattern and a space pattern. The hole pattern is surrounded by the corner portions (2a, 2b). The corner portions (2a, 2b) are formed at a front end of the space pattern and the side portions (3a, 3b) are formed in a longitudinal direction of the space pattern. Accordingly, since the bias value of the corner portion is larger than that of the side, the hole pattern is corrected to be larger than the space pattern by the amount of the difference. As a result, in case the hole pattern is mixed with the space pattern, dimension adjusting between the hole pattern and space pattern formed on a wafer can be performed easily.

If a length of one side of the rectangular pattern is taken as w, the corner portion is defined as a range in other sides orthogonal to the one side, and this range is present from a corner of the other sides to a position at a distance of no more than w/2 from this corner. The corner portion is defined in this way.

In the optimization step of the simulation parameter, a set of a polar coordinate function showing light distribution on the wafer and a coefficient corresponding to the set of the polar coordinate function are generated. Therefore, a product of the set (kernel) of the polar coordinate function, the coefficient and a device data showing presence/absence of a pattern at a predetermined position on the wafer is calculated, By repeatedly adding the product on the whole wafer surface, light intensity on the wafer can be calculated at a high speed.

The exposure mask further includes a translucent region. The translucent region is formed by a translucent film in which a phase of transmitted light through the translucent film is reversed by 180 degrees from a phase of the transmitted light through the transparent region.

This application is based upon and claims the benefit of priority from Japanese Patent Application No. 2007-315787, filed on Dec. 6, 2007, the disclosure whose is expressly incorporated herein in its entirety by reference.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A method for correcting optical proximity effect of a mask pattern for exposure light, the mask pattern including a rectangular pattern formed by a transparent region having a dimension of limiting resolution of exposure light, comprising:
performing exposure by means of an evaluating mask on which an evaluation pattern including the rectangular pattern is arranged so as to form a pattern on a wafer;
calculating an error between a simulation value obtained by a simulation of exposure, the simulation using the evaluation pattern and a dimension value of the pattern formed on the wafer; and
optimizing a simulation parameter so that the error becomes small,
wherein the simulation parameter comprises at least a first bias value and a second value, the first bias value corrects a corner portion of the rectangular pattern, and the second bias value corrects a side portion of the rectangular pattern.

2. The method according to claim 1, wherein the first bias value is larger than the second bias value.

3. The method according to claim 1, wherein the first bias value includes at least the following biases: a bias due to the mask 3D effect generated by unevenness between the transparent region and any region other than the transparent region; and a bias obtained by a rounding of the corner portion, the rounding being caused during irradiation of an electronic beam, and
the second bias value includes a bias due to the mask 3D effect.

4. The method according to claim 1, wherein the rectangular pattern comprises a hole pattern and a space pattern, the hole pattern being surrounded by the corner portion, and the corner portion is formed at a front end of the space pattern and the side portion is formed in a longitudinal direction of the space pattern.

5. The method according to claim 1, wherein if a length of one side of the rectangular pattern is taken as w, the corner portion is defined as a range in other sides orthogonal to the one side, and the range is present from a corner of the other sides to a position at a distance of no more than w/2 from the corner.

6. The method according to claim 1, wherein in optimizing the simulation parameter, a set of a polar coordinate function showing light distribution on the wafer and a coefficient corresponding to the set of the polar coordinate function are generated.

7. An exposure mask manufactured based on mask data, wherein the mask data undergoes correction of the optical proximity effect by a method for correcting optical proximity effect of a mask pattern for exposure light, the mask pattern including a rectangular pattern formed by a transparent region having a dimension of limiting resolution of exposure light, comprising:
performing exposure by means of an evaluating mask on which an evaluation pattern including the rectangular pattern is arranged so as to form a pattern on a wafer;
calculating an error between a simulation value obtained by a simulation of exposure, the simulation using the evaluation pattern and a dimension value of the pattern formed on the wafer; and
optimizing a simulation parameter so that the error becomes small,
wherein the simulation parameter comprises at least a first bias value and a second value, the first bias value corrects a corner portion of the rectangular pattern, and the second bias value corrects a side portion of the rectangular pattern.

8. The exposure mask according to claim 7, further comprising a translucent region, wherein the translucent region is formed by a translucent film in which a phase of transmitted light through the translucent film is reversed by 180 degrees from a phase of the transmitted light through the transparent region.
